(19) United States
(12) Patent Application Publication
(10) Pub. No.: US 2025/0391710 A1
(43) Pub. Date: Dec. 25, 2025

(54) SEMICONDUCTOR DEVICE, PACKAGE AND MANUFACTURING METHOD THEREOF

(71) Applicant: Taiwan Semiconductor Manufacturing Company, Ltd., Hsinchu (TW)

(72) Inventors: Kuo Wen Chen, Hsinchu City (TW); Jyun-Lin Wu, Hsinchu City (TW); Yao-Chun Chuang, Hsinchu City (TW); Yinlung Lu, Hsinchu (TW)

(73) Assignee: Taiwan Semiconductor Manufacturing Company, Ltd., Hsinchu (TW)

(21) Appl. No.: 18/749,559

(22) Filed: Jun. 20, 2024

(51) Int. Cl. H01L 21/66; H01L 23/00; H01L 23/31; H01L 23/36; H01L 23/48; H01L 23/49; H01L 23/498; H01L 25/00; H01L 25/10

(52) U.S. Cl. CPC H01L 22/32; H01L 23/481; H01L 24/24; H01L 24/25; H01L 25/105; H01L 25/50; H01L 23/3107; H01L 23/36; H01L 23/49; H01L 23/49816; H01L 24/16; H01L 24/32; H01L 24/73; H01L 2224/16227; H01L 2224/24146; H01L 2224/24225; H01L 2224/2518; H01L 2224/32225; H01L 2224/73204

(57) ABSTRACT

The present disclosure relates to a package. The package comprises an interconnect die, an encapsulant, a first redistribution structure and an integrated circuit die. The interconnect die comprises a semiconductor substrate and an interconnect structure. The interconnect structure is disposed over the semiconductor substrate and comprising a first test circuit. The encapsulant surrounds the interconnect die. The first redistribution structure is disposed over the interconnect die and the encapsulant. The first redistribution structure comprises a second test circuit, a first test structure, a second test structure and bonding structures. The second test circuit is connected with the first test circuit. The first test structure and the second test structure are connected with the second test circuit. The integrated circuit die is electrically connected to the bonding structures and separated from the first test structure and the second test structure.

### BACKGROUND

The semiconductor integrated circuit (IC) industry has witnessed an accelerated expansion over the years. Technological advancements in the domain of IC materials and design have given birth to an array of IC generations, each one boasting smaller yet more intricate circuits than its predecessor. As IC evolution progresses, a noticeable increase in functional density, which refers to the quantity of interconnected devices per chip area, has been observed. Concurrently, there has been a reduction in geometry size. This process of scaling down generally presents numerous advantages, including the enhancement of production efficiency and a significant reduction in associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1I are schematic cross-sectional views of various stages in a manufacturing method of a package in accordance with some embodiments of the disclosure.

FIG. 2 is a schematic cross-sectional view of a package in accordance with some embodiments of the disclosure.

FIG. 3 is a schematic top view of an electrical test in accordance with some embodiments of the disclosure.

FIG. 4 is a schematic top view of an electrical test in accordance with some embodiments of the disclosure.

FIG. 5 is a schematic top view of an electrical test in accordance with some embodiments of the disclosure.

FIG. 6 is a schematic top view of an electrical test in accordance with some embodiments of the disclosure.

FIG. 7 is a schematic top view of an electrical test in accordance with some embodiments of the disclosure.

FIG. 8 is a schematic top view of a package in accordance with some embodiments of the disclosure.

FIG. 9 is a schematic cross-sectional view of a package in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a chip-on-wafer-on-substrate (CoWoS) package, multiple chips are stacked on a wafer, which is then combined with a substrate. This packaging method may effectively enhance the performance and efficiency of the chips. Additionally, CoWoS package may provide high signal transmission speeds and low power consumption, making it widely applicable in fields such as high-performance computing, network communications, and artificial intelligence.

In some embodiments, a reconstituted wafer comprising multiple local silicon interconnect dies (LSIs), an encapsulant surrounding the LSIs, and through insulator vias (TIVs) embedded in the encapsulant may be used in a CoWoS package. In this case, a front-side redistribution structure is first formed over the reconstituted wafer, followed by the bonding of chips to the front-side redistribution structure. After flipping the structure, a back-side redistribution structure is formed over the back of the reconstituted wafer. The resulting structure is then cut and combined with a package substrate. If the LSIs are not placed in the correct position, it may easily lead to leakage problems between the front-side redistribution structure and the LSIs and/or between the back-side redistribution structure and the LSIs, thereby affecting the yield of the final product. If it can be confirmed whether the LSIs are correctly positioned before attaching the chips to the front-side redistribution structure, it would prevent the chips from being combined with the reconstituted wafer where the LSIs are not correctly placed, thereby reducing the waste of chips. In some embodiments, the placement of the LSIs is probed by test circuits in the front-side redistribution structure and the LSIs, thereby improving production yield and reducing costs.

Other features and processes may also be included. For example, testing structures may be included to aid in the verification testing of the 3D packaging or 3DIC devices. The testing structures may include, for example, test structures formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

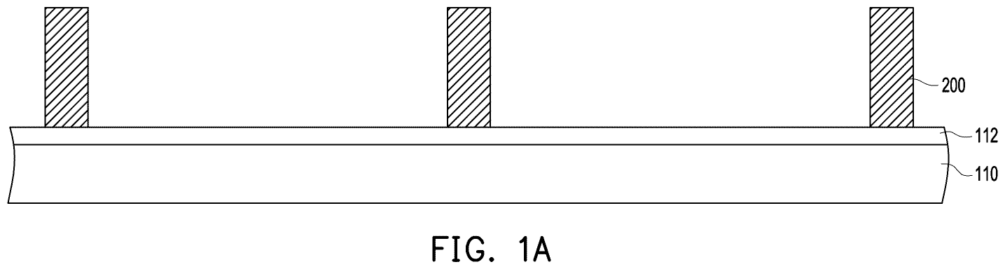

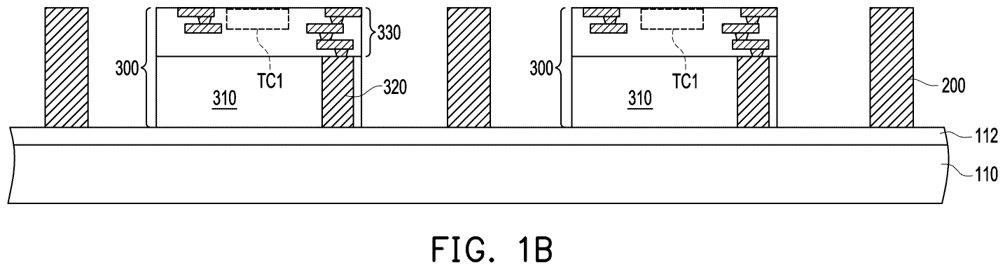

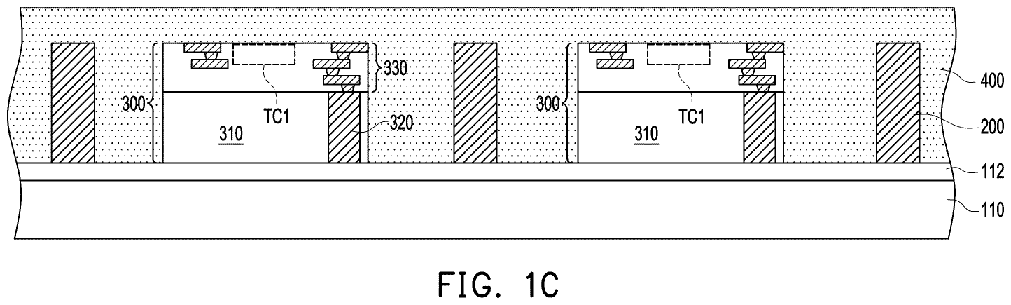

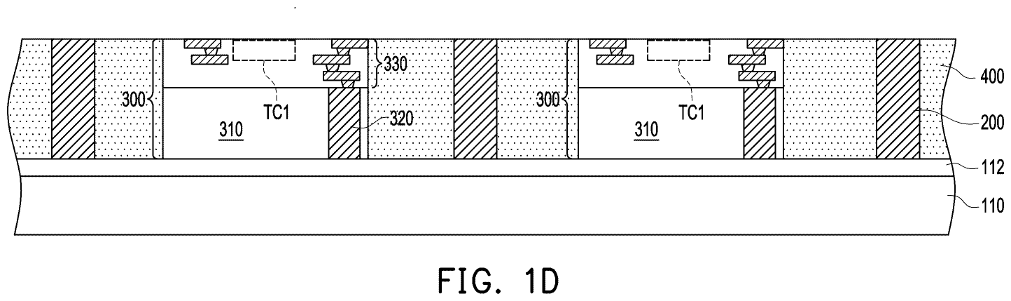

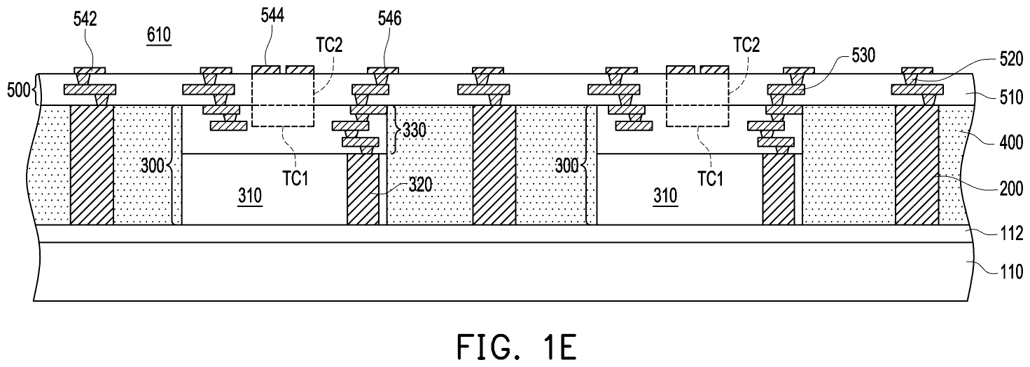

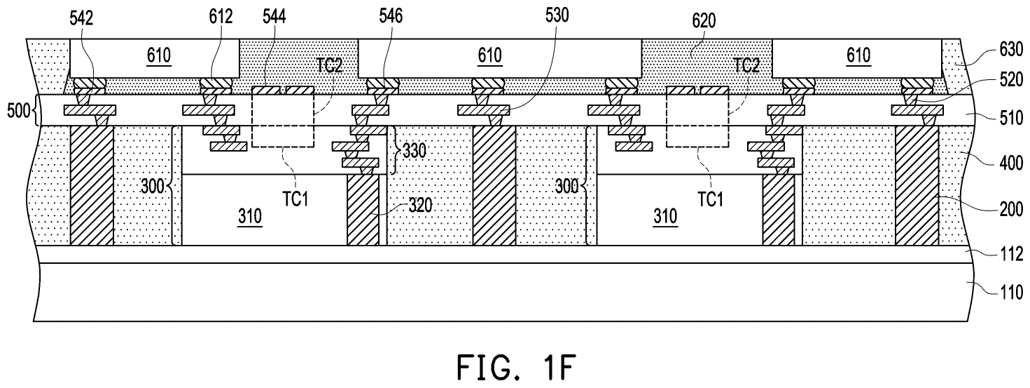

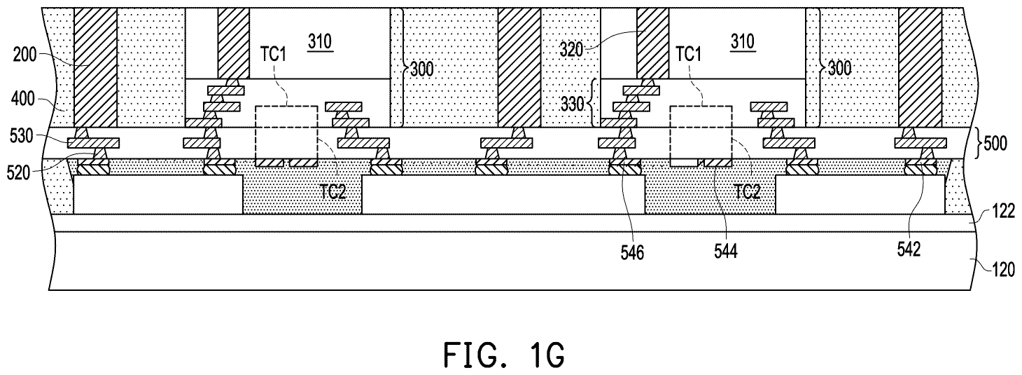

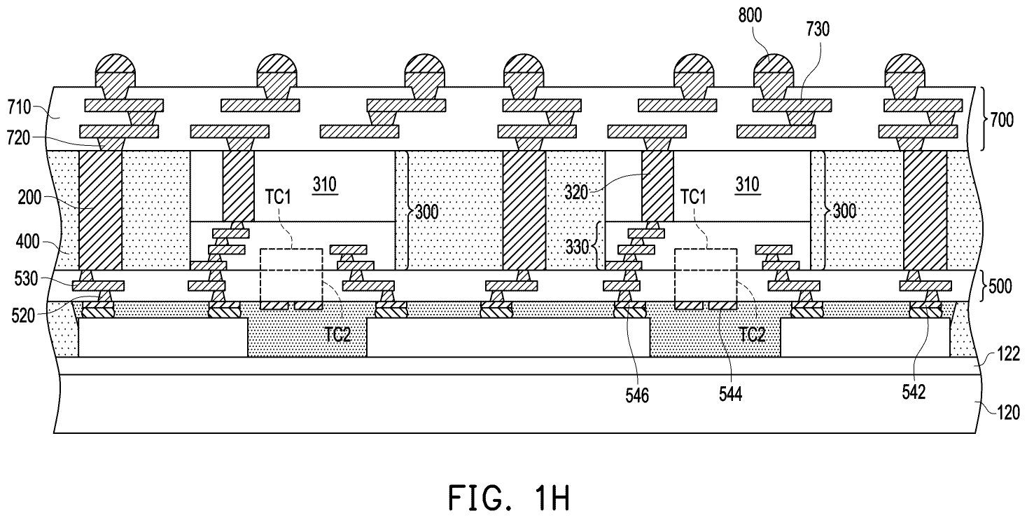

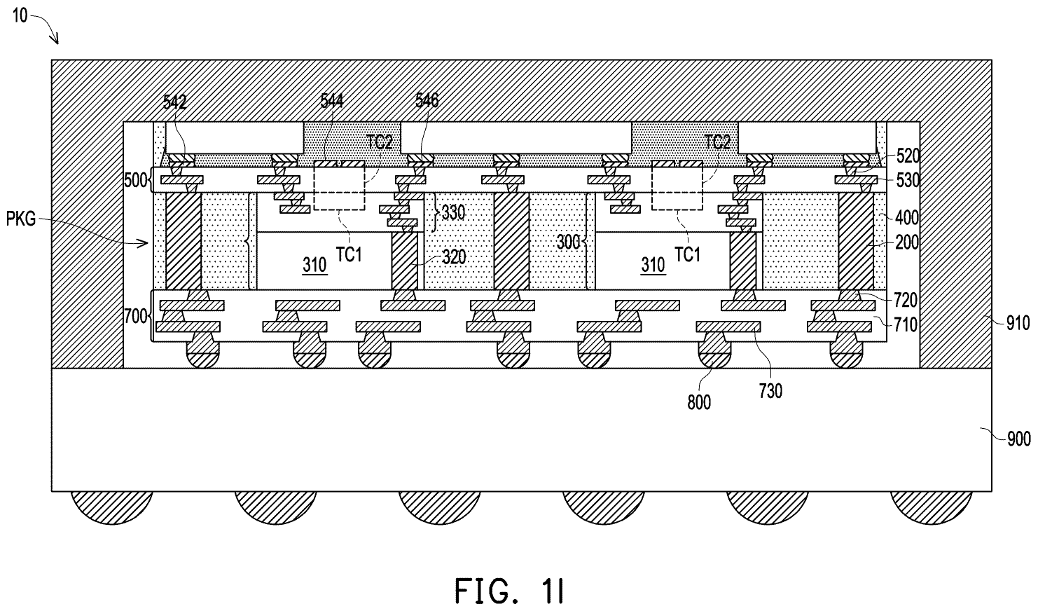

FIG. 1A through FIG. 1I are schematic cross-sectional views of various stages in a manufacturing method of a package 10 in accordance with some embodiments of the disclosure. Referring to FIG. 1A, a first carrier 110 is provided, and a release layer 112 is formed over the first carrier 110. The first carrier 110 may be a glass carrier, a ceramic carrier, or the like. The release layer 112 may be formed of a polymer-based material, which may be removed along with the first carrier 110 from the overlying structures that will be formed in subsequent steps. In some embodiments, the release layer 112 is an epoxy-based thermal-release material, which loses its adhesive property when heated, such as a light-to-heat-conversion (LTHC) release coating. In other embodiments, the release layer 112 may be an ultra-violet (UV) glue, which loses its adhesive property when exposed to UV lights. The release layer 112 may be dispensed as a liquid and cured, may be a laminate film laminated onto the first carrier 110, or may be the like. The top surface of the release layer 112 may be planarized and may have a high degree of planarity.

A plurality of conductive pillars 200 are placed over the first carrier 110. As an example to form the conductive pillars 200, a photoresist is formed and patterned on the release layer 112. The photoresist may be formed by spin coating or the like and may be exposed to light for patterning. The pattern of the photoresist corresponds to the conductive pillars 200. A conductive material is then formed in the openings of the photoresist. The photoresist is then removed. The photoresist may be removed by any acceptable ashing or stripping process, such as using an oxygen plasma or the like. The remaining portions of the conductive material forms the conductive pillars 200. In alternative embodiments, the conductive pillars 200 may be provided by a pick and place (PNP) process.

Referring to FIG. 1B, a plurality of interconnect dies 300 are provided over the first carrier 110. In some embodiments, the interconnect dies 300 are provided by a PNP process. Each interconnect dies 300 includes a semiconductor substrate 310, at least one of through-substrate via (TSV) 320, and an interconnect structure 330.

The semiconductor substrate 310 may be a substrate of silicon, doped or undoped, or an active layer of a semiconductor-on-insulator (SOI) substrate. When the semiconductor substrate 310 comprises silicon, the interconnect dies 300 may be referred to as a local silicon interconnect (LSI) die. In other embodiments, the semiconductor substrate 310 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. In some embodiments, the semiconductor substrate 310 has an active surface (e.g., the surface facing upward) and an inactive surface (e.g., the surface facing downward). Devices are at the active surface of the semiconductor substrate 310. The devices may be active devices (e.g., transistors, diodes, etc.), capacitors, resistors, etc. The inactive surface may be free from devices. In other embodiments, there is no active device disposed within the semiconductor substrate 310.

The TSV 320 is disposed in the semiconductor substrate 310. In the illustrated embodiment, the TSV 320 extends through the substrate 310, so that it is in contact with the release layer 112. In another embodiment, a material of substrate 310 may cover the bottom of the TSV 320, so that the TSV 320 is separated from the release layer 112. In such an embodiment, the bottom surface of the TSV 320 may be exposed in a subsequent process through a planarization process, such as chemical-mechanical polishing (CMP), a grinding process, or the like.

The interconnect structure 330 is disposed over the semiconductor substrate 310 and the TSV 320. The interconnect structure 330 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. In some embodiments, openings for accommodating metallization layers are formed in the dielectric layer(s) through etching or photolithography processes.

The metallization layers may include vias and/or conductive lines to interconnect the features of the semiconductor substrate 310. The metallization layers may be formed of a conductive material, such as a metal, such as copper, cobalt, aluminum, gold, combinations thereof, or the like. The interconnect structure 330 may be formed by a damascene process, such as a single damascene process, a dual damascene process, or the like.

Some components (such as certain metallization layers) within the interconnect structure 330 form a first test circuit TC1. The first test circuit TC1 is suitable for an electrical test in subsequent processes. FIG. 1B omits the structure of the first test circuit TC1. The structure of the first test circuit TC1 may be referred to in the later embodiments.

Additionally, in some embodiments, the topmost dielectric layer of the interconnect structure 330 includes a molding layer. Initially, the molding layer encapsulates the topmost metallization layer of the interconnect structure 330, and the topmost metallization layer of the interconnect structure 330 (including a portion of the first test circuit TC1) is exposed by the subsequent planarization process.

Referring to FIG. 1C, an encapsulant 400 is applied over the first carrier 110 and surrounding the interconnect dies 300 and the conductive pillars 200. After formation, the encapsulant 400 encapsulates the interconnect dies 300 and the conductive pillars 200. The encapsulant 400 may be a molding compound, epoxy, or the like. In some embodiments, the encapsulant 400 includes a polymer resin having fillers disposed therein. The encapsulant 400 may be applied by compression molding, transfer molding, or the like, and may be dispensed over the first carrier 110 such that the interconnect dies 300 and the conductive pillars 200 are buried or covered. The encapsulant 400 is further dispensed in gap regions between the interconnect dies 300 and the conductive pillars 200. The encapsulant 400 may be applied in liquid or semi-liquid form and then subsequently cured.

Referring to FIG. 1D, a planarization process may be performed on the encapsulant 400 to expose the interconnect dies 300 and the conductive pillars 200. In some embodiments, the planarization process also removes a portion of the topmost molding layer in the interconnect structure 330, thereby exposing the topmost metallization layer of the interconnect structure 330 (including a portion of the first test circuit TC1). After the planarization process, top surfaces of the encapsulant 400, the interconnect structure 330, and the conductive pillars 200 are substantially coplanar (within process variations) such that they are level with one another. The planarization process may be, for example, a chemical-mechanical polish (CMP), a grinding process, or the like. In some embodiments, the planarization process may be omitted, for example, if the topmost metallization layer of the interconnect structure 330 and the conductive pillars 200 are already exposed. In this embodiment, the conductive pillars 200, which are surrounded by the encapsulant 400, may also be referred to as through insulator vias (TIVs).

Referring to FIG. 1E, a first redistribution structure 500 is formed over the conductive pillars 200, the interconnect dies 300, and the encapsulant 400.

The first redistribution structure 500 includes one or more dielectric layers 510 and one or more metallization layers (sometimes referred to as redistribution layers or redistribution lines) among the dielectric layer(s) 510. For example, the first redistribution structure 500 may include a plurality of metallization layers separated from each other by respective dielectric layer(s) 510. Acceptable dielectric materials for the dielectric layer(s) 510 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. In some embodiments, openings for accommodating metallization layers are formed in the dielectric layer(s) 510 through etching or photolithography processes.

The metallization layers may include conductive vias 520 extending along a vertical direction and/or conductive lines 530 extending along a horizontal direction. The metallization layers may be formed of a conductive material, such as a metal, such as copper, cobalt, aluminum, gold, combinations thereof, or the like. The first redistribution structure 500 may be formed by a damascene process, such as a single damascene process, a dual damascene process, or the like.

The metallization layers of the first redistribution structure 500 are connected to the conductive pillars 200 and the interconnect dies 300. For example, at least one of the conductive via 520 is connected to the interconnect structure 330 of the interconnect dies 300.

In this embodiment, portions of the metallization layers in the first redistribution structure 500, including some of the conductive lines 530 and some of the conductive vias 520, constitute a second test circuit TC2. The second test circuit TC2 is suitable for an electrical test in subsequent processes. FIG. 1D omits the structure of the second test circuit TC2. The structure of the second test circuit TC2 may be referred to in the later embodiments. The second test circuit TC2 in the first redistribution structure 500 is connected with the first test circuit TC1 in the interconnect dies 300.

In some embodiments, the first redistribution structure 500 includes multiple test structures 544 and bonding structures 542, 546 located at the topmost layer. The test structures 544 are connected with the second test circuit TC2. The bonding structures 542 are electrically connected with the conductive pillars 200. The bonding structures 546 are electrically connected with the TSV 320.

In some embodiments, the bonding structures 542, 544 comprise under-bump metallurgy layers (UBM layers). The test structures 544 and the bonding structures 542, 546 are formed simultaneously and comprise the same material. In other embodiments, the test structures 544 and the bonding structures 542, 546 may be formed through different processes and may include different materials. In other embodiments, the test structures 544 and the bonding structures 542, 544 may be pads, micro bumps, solder, or other conductive structures.

After forming the first redistribution structure 500, the test structures 544 are probed to conduct an electrical test on the second test circuit TC2 and the first test circuit TC1. For instance, a four point probe resistivity measurement (Kelvin sensing) is conducted using the test structures 544. It should be noted that the number of test structures 544 on the second test circuit TC2 can be adjusted according to actual needs, and is not limited to only two test structures 544 per second test circuit TC2. In some embodiments, if there are errors in the PNP process of the interconnect die 300, it may result in the interconnect die 300 not being precisely placed in the correct position. Consequently, the relative position between the second test circuit TC2 and the first test circuit TC1 may deviate, thereby affecting the electrical contact between the first test circuit TC1 and the second test circuit TC2 and leading to changes in electrical resistance. In some embodiments, the electrical resistance of the first test circuit TC1 and the second test circuit TC2 is confirmed through the four point probe resistivity measurement, thereby inspecting whether the interconnect dies 300 are correctly placed. Additionally, each interconnect die 300 can include more than one first test circuit TC1. In other words, more than one test can be conducted on each interconnect die 300.

Referring to FIG. 1F, integrated circuit dies 610 are positioned over the bonding structures 542, 546. The integrated circuit dies 610 may include a System on Chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the integrated circuit dies 610 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die.

In some embodiments, each of the integrated circuit dies 610 is connected to the corresponding bonding structures 542, 546 through the corresponding connectors 612. The connectors 610 are formed on the integrated circuit dies 610 and/or some of the bonding structures 542, 546. The connectors 610 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The connectors 610 may include a conductive material such as solder, copper, aluminum, gold, nickel, silver, palladium, tin, the like, or a combination thereof. In some embodiments, the connectors 610 are formed by initially forming a layer of solder on the bonding structures 542, 546 through evaporation, electroplating, printing, solder transfer, ball placement, or the like. Once a layer of solder has been formed on the structure, a reflow may be performed in order to shape the material into the desired bump shapes. The integrated circuit dies 610 are connected to the bonding structures 542, 546 using the connectors 610.

In certain embodiments, the first test circuit TC1 and the second test circuit TC2 are electrically isolated from all of the integrated circuit dies 610 and all of the conductive pillars 200, but the disclosure is not limited to this. In this embodiment, the connectors 612 are not formed on the test structures 544. Consequently, the integrated circuit dies 610 are separated from the test structures 544. In another embodiment, a portion of the connectors 612 may be formed on the test structures 544. However, these connectors 612 formed on the test structures 544 will not be connected to the integrated circuit dies 610, or connected to the dummy pads of the integrated circuit dies 610. In other words, in the subsequent structure, the first test circuit TC1 and the second test circuit TC2 are floating.

An underfill 620 is formed between the integrated circuit dies 610 and the first redistribution structure 500. The underfill 620 covers top surfaces of the test structures 544. The underfill 620 is formed around the connectors 612. The underfill 620 may reduce stress and protect the joints resulting from the reflowing of the connectors 612. The underfill 620 may also be included to adhere the integrated circuit dies 610 to the first redistribution structure 500 and provide structural support and environmental protection. The underfill 620 may be formed of a molding compound, an epoxy, or the like. The underfill 620 may be formed by a capillary flow process after the integrated circuit dies 610 are attached, or may be formed by any suitable deposition method before the integrated circuit dies 610 are attached. The underfill 620 may be applied in liquid or semi-liquid form and then subsequently cured.

An encapsulant 630 is formed around the integrated circuit dies 610 and the underfill 620 (if present) or the connectors 612. After formation, the encapsulant 630 encapsulates the integrated circuit dies 610 and the underfill 620 (if present) or the connectors 612. The encapsulant 630 may be a molding compound, epoxy, or the like. In some embodiments, the encapsulant 630 includes a polymer resin having fillers disposed therein. The encapsulant 630 may be applied by compression molding, transfer molding, or the like, and may be dispensed such that the integrated circuit dies 610 are buried or covered. The encapsulant 630 may be applied in liquid or semi-liquid form and then subsequently cured. An optional planarization process may be performed on the encapsulant 630 to expose the integrated circuit dies 610. The planarization process may remove material of the encapsulant 630 until the integrated circuit dies 610 are exposed. After the planarization process, top surfaces of the encapsulant 630 and the integrated circuit dies 610 are substantially coplanar (within process variations) such that they are level with one another. The planarization process may be, for example, a chemical-mechanical polish (CMP), a grinding process, or the like. In some embodiments, the planarization process may be omitted.

Referring to FIG. 1G, the structure is flipped and placed on a second carrier 120. Subsequently, the first carrier 110 is removed. A release layer 122 is formed over the second carrier 120. The second carrier 120 may be a glass carrier, a ceramic carrier, or the like. The release layer 122 may be formed of a polymer-based material, which may be removed along with the second carrier 120 from the overlying structures that will be formed in subsequent steps. In some embodiments, the release layer 122 is an epoxy-based thermal-release material, which loses its adhesive property when heated, such as a light-to-heat-conversion (LTHC) release coating. In other embodiments, the release layer 122 may be an ultra-violet (UV) glue, which loses its adhesive property when exposed to UV lights. The release layer 122 may be dispensed as a liquid and cured, may be a laminate film laminated onto the second carrier 120, or may be the like. The top surface of the release layer 122 may be planarized and may have a high degree of planarity.

Referring to FIG. 1H, a second redistribution structure 700 is formed over the conductive pillars 200, the interconnect dies 300, and the encapsulant 400. The conductive pillars 200, the interconnect dies 300, and the encapsulant 400 are located between the first redistribution structure 500 and the second redistribution structure 700. In some embodiments, the first test circuit TC1 and the second test circuit TC2 are electrically isolated from the through substrate via 320 and the second redistribution structure 700.

The second redistribution structure 700 includes one or more dielectric layers 710 and one or more metallization layers (sometimes referred to as redistribution layers or redistribution lines) among the dielectric layer(s) 710. For example, the second redistribution structure 700 may include a plurality of metallization layers separated from each other by respective dielectric layer(s) 710. Acceptable dielectric materials for the dielectric layer(s) 710 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. In some embodiments, openings for accommodating metallization layers are formed in the dielectric layer(s) 710 through etching or photolithography processes.

The metallization layers may include conductive vias 720 extending along a vertical direction and/or conductive lines 730 extending along a horizontal direction. The metallization layers may be formed of a conductive material, such as a metal, such as copper, cobalt, aluminum, gold, combinations thereof, or the like. The second redistribution structure 700 may be formed by a damascene process, such as a single damascene process, a dual damascene process, or the like. In some embodiments, the top most metallization layer in the second redistribution structure 700 may include under-bump metallurgy layers (UBM layers).

The metallization layers of the second redistribution structure 700 are connected to the conductive pillars 200 and the TSV 320. For example, at least one of the conductive via 720 is connected to the TSV 320 of the interconnect dies 300. The TSV 320 electrically connected the second redistribution structure 700 to the interconnect structure 330.

Conductive connectors 800 are formed on the second redistribution structure 700, for instance, on the UBM layers in the second redistribution structure 700. The conductive connectors 800 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 800 may include a conductive material such as solder, copper, aluminum, gold, nickel, silver, palladium, tin, the like, or a combination thereof. In some embodiments, the conductive connectors 800 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 800 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments, after forming the conductive connectors 800, an electrical test is performed on the structure.

A singulation process is executed on the structure to obtain individual package components PKG, as shown in FIG. 1I. The singulation process may be a sawing process, a laser cutting process, or similar. The package components PKG is than attached to package substrate 900 by bonding the second redistribution structure 700 to the package substrate 900 using the conductive connectors 800 on the lower surface of the second redistribution structure 700. An array of solder balls may be formed on the lower surface of the package substrate 900.

A heat spreader 910 is optionally attached to the package component PKG. The heat spreader 910 may be a thermal lid, a heatsink, or the like. In the illustrated embodiment, the heat spreader 910 is a thermal lid which is also attached to the package substrate 900. A recess is in the bottom of the thermal lid so that the thermal lid can cover the package component PKG. In another embodiment, the heat spreader 910 is a heatsink.

The heat spreader 910 may be formed of a material with high thermal conductivity, such as a metal, such as copper, steel, iron, or the like. The heat spreader 910 protects the package component PKG and forms a thermal pathway to conduct heat from the various components of the package component PKG (e.g., the integrated circuit dies 610). The heat spreader 910 is thermally coupled to the back-side surface of the package component PKG. In some embodiments, an adhesive layer (not shown) is used to adhere the heat spreader 910 to the package component PKG. The adhesive layer may be a thermal interface material (TIM), a die attach film (DAF), or the like.

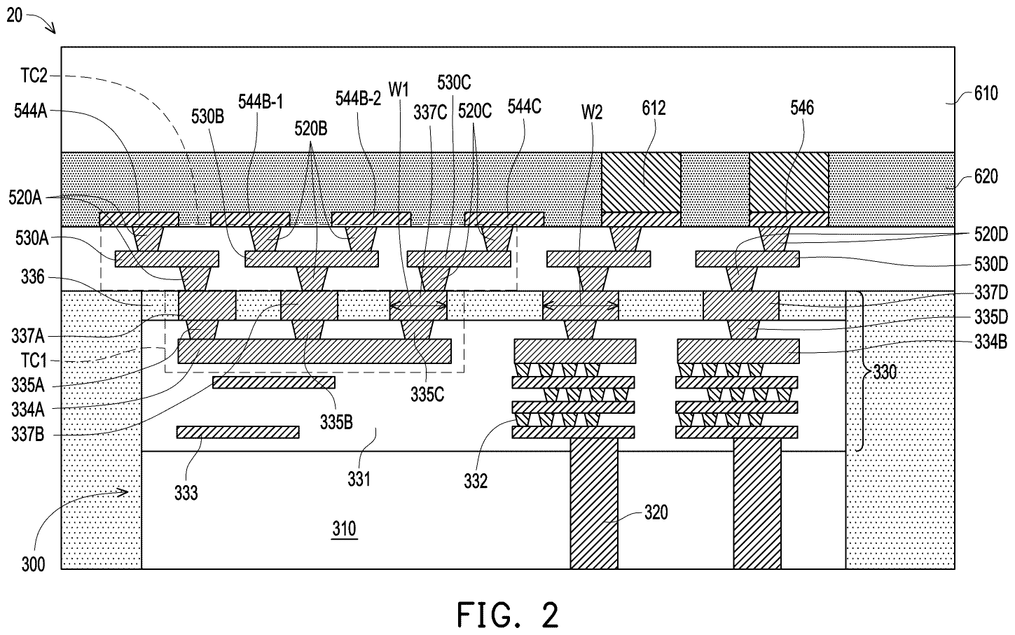

FIG. 2 is a schematic cross-sectional view of a package 20 in accordance with some embodiments of the disclosure. The package 20 shown in FIG. 2 may be manufactured using the process described in FIGS. 1A to 1I, for the same parts, please refer to the previous description. Referring to FIG. 2, the interconnect structure 330 of the interconnect die 300 includes interconnect layers 333, vias 332, connection structures 334A, 334B, and conductive vias 335A-335D embedded in at least one dielectric layer 331, and the interconnect structure 330 further includes contact pads 337A-337D embedded in a molding layer 336.

The first test circuit TC1 includes the first connection structure 334A, the conductive vias 335A-335C, and the contact pads 337A-337C. The contact pads 337A-337C are respectively disposed over the first conductive vias 335A-335C, and the contact pads 337A-337C are respectively electrically connected to the first connection structure 334A through the conductive vias 335A-335C. In the first test circuit TC1, the conductive vias 335A-335C contact the top surface of the first connection structure 334A, where the conductive via 335B is located between the conductive via 335A and the conductive via 335C. In this embodiment, three conductive vias are in contact with the first connection structure 334A are exemplified, but the disclosure is not limited thereto. In other embodiments, four conductive vias are in contact with the top surface of the first connection structure 334A.

On the other hand, the conductive pads 337D are electrically connected to the second conductive vias 335D and the second connection structures 334B, and further electrically connected to the TSVs 320 through the corresponding interconnect layers 333 and the corresponding vias 332.

In some embodiments, the contact pads 337A-337C and conductive pads 337D are formed by patterning the same conductive layer, and the top surfaces of the conductive pads 337D are coplanar with the top surfaces of the contact pad 337A-337C. In certain embodiments, the width W1 of the contact pads 337A-337C may be the same as or different from the width W2 of the conductive pads 337D. For instance, the width W1 may be less than the width W2.

The first redistribution structure 500 is disposed over the interconnect structure 330. The first redistribution structure 500 includes conductive vias 520A-520D and conductive lines 530A-530D. The conductive vias 520A and the conductive line(s) 530A electrically connect the test structure 544A to the contact pad 337A. The conductive vias 520B and the conductive line(s) 530B electrically connect the test structures 544B-1, 544B-2 to the contact pad 337B. The conductive vias 520C and the conductive line(s) 530C electrically connect the test structure 544C to the contact pad 337C. In the first redistribution structure 500, an electrically conductive path between the test structure 544A and the contact via 520A connected with the contact pad 337A, an electrically conductive path between the test structure 544B-1 (or the test structure 544B-2) and the second contact via 520B connected with the contact pad 337B, and an electrically conductive path between the test structure 544C and the contact via 520C connected with the contact pad 337C are separated from each other. In other words, the conductive paths corresponding to test structures 544A, 544B-1 (or 544B-2), 544C in the first redistribution structure 500 are separated from each other. However, test structures 544A, 544B-1 (or 544B-2), 544C are electrically connected to each other through the first test circuit TC1.

In certain embodiments, prior to bonding the integrated circuit die 610 to the first redistribution structure 500, a four-point probe resistivity measurement is performed using test structures 544A, 544B-1, 544B-2, 544C. If the interconnect die 300 exhibits deviations during the PNP process, it will affect the electrical connection between the conductive vias 520A-520D and the contact pads 337A-337D. If the deviation in the PNP process is too large, it may lead to a reduction in the contact area between the conductive vias 520A-520D and the contact pads 337A-337D (for example, part of the bottom surface of conductive vias 520A-520D contacts the molding layer 336), or even result in conductive vias 520A-520D only contacting the molding layer 336 and not contacting the contact pads 337A-337D. Since the contact area therebetween is related to the electrical resistance value, the correct placement of the interconnect die 300 can be confirmed by measuring the electrical resistance value.

The placement of the contact pads 337A-337D can be adjusted according to actual needs. In some embodiments, the contact pads 337A-337D can be hidden under the integrated circuit die 610, with the contact pads 337A-337D located between the integrated circuit die 610 and the semiconductor substrate 310. In other embodiments, the contact pads 337A-337C do not overlap with the integrated circuit die 610.

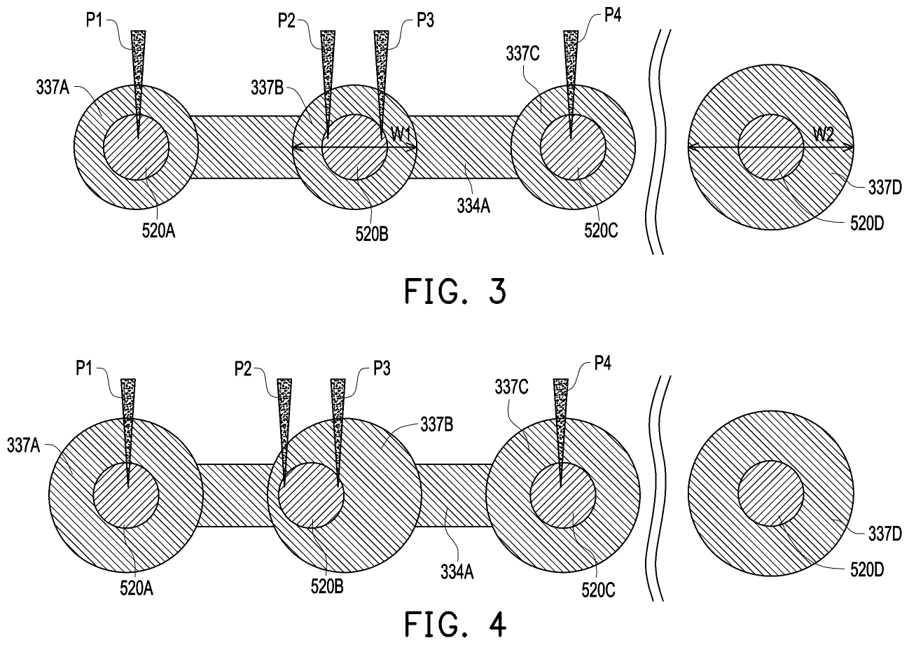

FIG. 3 is a schematic top view of an electrical test in accordance with some embodiments of the disclosure. FIG. 3 illustrates the contact pads 337A-337D in the package and the conductive vias 520A-520D respectively in contact with the contact pads 337A-337D. Further details about other components in the package may be referred to previous embodiments. Referring to FIG. 3, probes P1-P4 are used to conduct the four point probe resistivity measurement. It is noteworthy that probes P1-P4 are actually in contact with the test structures corresponding to the conductive vias 520A-520C (refer to FIG. 2 and its related description), rather than directly contacting the conductive vias 520A-520C. In the embodiment of FIG. 3, the probe P1 contacts the test structure corresponding to the conductive via 520A (for instance, the test structure 544A in FIG. 2), the probes P2 and P3 respectively contact the test structures corresponding to the conductive via 520B (for instance, the test structures 544B-1, 544B-2 in FIG. 2), and the probe P4 contacts the test structure corresponding to the conductive via 520C (for instance, the test structure 544C in FIG. 2). In some embodiments, a voltage difference is provided between probes P3 and P4, and the current between probes P1 and P2 is measured. The resistivity may be obtained through the four point probe resistivity measurement.

In some embodiments, by making the width W1 less than the width W2, the electrical resistance variation caused by the process errors may be increased. For example, after reducing the width W1, the conductive vias 520A-520C will be more likely to deviate from the contact pads 337A-337C. Therefore, by reducing the width W1, the process deviation of the PNP process can be detected more accurately. In other words, if the conductive vias 520A-520C deviate from the contact pads 337A-337C due to minute deviation, it would result in parts of the bottom surface of the conductive vias 520A-520C not touching the contact pads 337A-337C, thereby affecting the electric resistance.

FIG. 4 is a schematic top view of an electrical test in accordance with some embodiments of the disclosure. The difference from the embodiment in FIG. 3 is that the embodiment in FIG. 4 increases the impact of the PNP process deviation on electric resistance by changing the default position of the conductive vias 520B. For example, the center of the conductive via 520B is set to not align with the center of the contact pad 337B, so the conductive via 520B are more likely to exceed the range of the contact pad 337B due to the process deviation of the PNP process. In FIG. 4, if the interconnect dies shift slightly to the right due to process deviation, it will cause the conductive vias 520B to exceed the left side of the contact pad 337B.

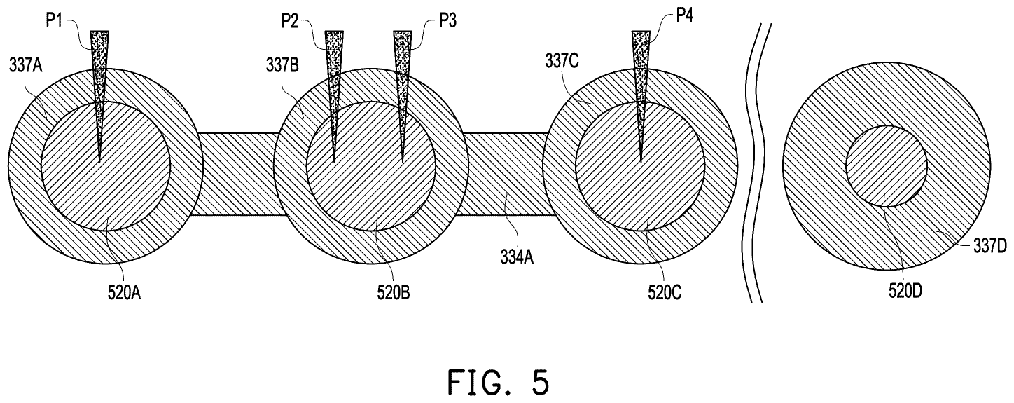

FIG. 5 is a schematic top view of an electrical test in accordance with some embodiments of the disclosure. The distinction from the embodiment in FIG. 3 is that the embodiment in FIG. 4 enhances the influence of the PNP process deviation on electrical resistance by increasing the width of the conductive vias 520A-520C. By expanding the width of the conductive vias 520A-520C, the conductive vias 520A-520C are more likely to exceed the range of the contact pads 337A-337C due to process deviation.

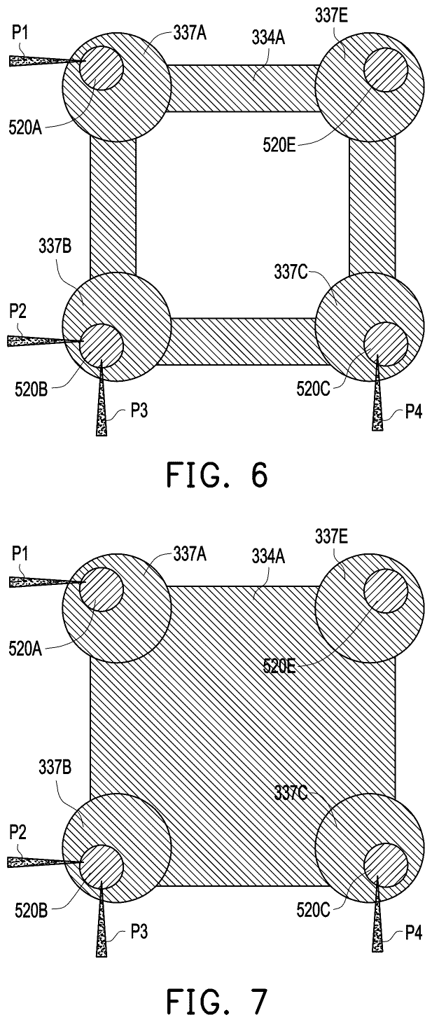

FIG. 6 is a schematic top view of an electrical test in accordance with some embodiments of the disclosure. In the embodiment illustrated in FIG. 6, the contact pads 337A-337C, 337E are connected to the same first connection structure 334A. In some embodiments, the first connection structure 334A has a ring-like structure, such as a rectangular ring, circular ring, etc., but this disclosure is not limited to this. In other embodiments, the first connection structure 334A has a whole piece structure, as shown in FIG. 7. The first connection structure 334A can be rectangular, circular, polygonal, or of other geometric shapes.

The conductive vias 520A-520C, 520E are respectively disposed on the contact pads 337A-337C, 337E. In this embodiment, each of the conductive vias 520A-520C, 520E corresponds to two test structures. In other words, each of the contact pads 337A-337C, 337E can be probed by two probes. Furthermore, the conductive paths corresponding to each contact pad 337A-337C, 337E are independent of each other in the first redistribution layer.

As an example of detecting the deviation between the conductive via 520B and the contact pad 337B, the probe P1 is connected to one of the two test structures corresponding to the contact pad 337A, the probes P2 and P3 are respectively connected to the two test structures corresponding to the contact pad 337B, and the probe P4 is connected to one of the two test structures corresponding to the contact pad 337C. In some embodiments, a voltage difference is applied between probes P3 and P4, and the current between probes P1 and P2 is measured. The electrical resistivity can be obtained through the four-point probe resistivity measurement.

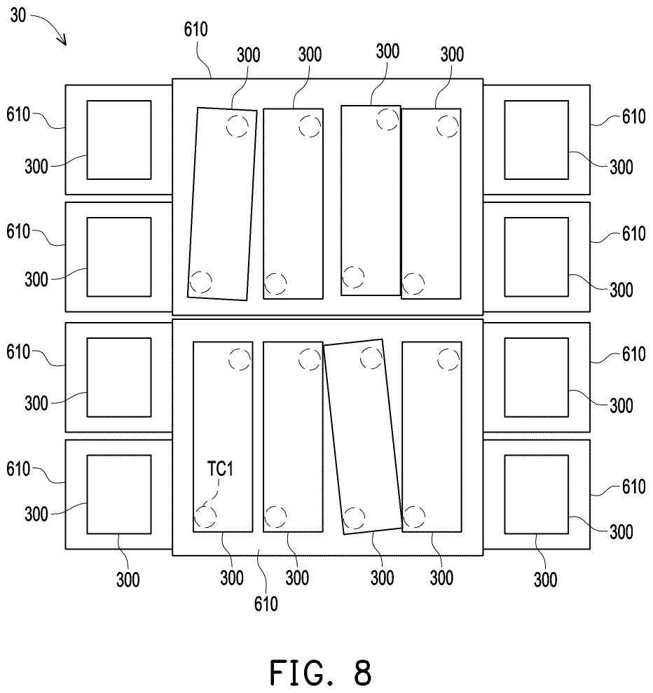

FIG. 8 is a schematic top view of a package in accordance with some embodiments of the disclosure. For clarity, interconnect dies 300 and integrated circuit dies 610 are depicted in a perspective view in FIG. 8. Referring to FIG. 8, a package 30 includes an array of interconnect dies 300 and an array of integrated circuit dies 610. During the manufacturing process of package 30, the first test circuits TC1 in at least a portion of the interconnect dies 300 may be used to detect if there is excessive positional deviation in the interconnect dies 300. If a significant positional deviation is detected in the interconnect dies 300, rework or scrapping can be performed before the integrated circuit dies 610 are combined with the first redistribution structure (refer to the first redistribution structure 500 in FIG. 1E), thereby avoiding wastage of the integrated circuit dies 610.

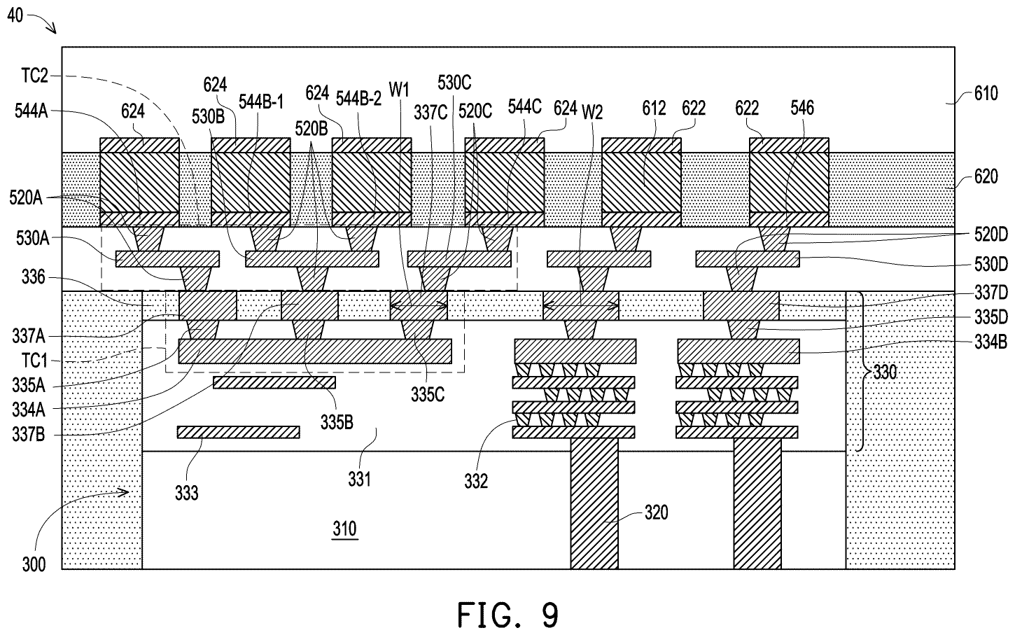

FIG. 9 is a schematic cross-sectional view of a package 40 in accordance with some embodiments of the disclosure. It should be noted herein that, in embodiments provided in FIG. 9, element numerals and partial content of the embodiments provided in FIG. 2 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 9, in this embodiment, the integrated circuit dies 610 are connected to the test structures 544 and the bonding structures 542, 546 through connectors 612. For example, the integrated circuit dies 610 include first pads 622 and second pads 624, wherein the first pads 622 are electrically connected to the bonding structures 542, 546, and the second pads 624 are electrically connected to the test structures 544. In some embodiments, the second pads 624 are, for example, dummy pads. For instance, the first pads 622 are electrically connected to at least some active devices in the integrated circuit dies 610, while the second pads 624 are not electrically connected to any active devices in the integrated circuit dies 610. The second pads 624 are, for example, floating. Through the configuration of second pads 624, the bonding strength between the integrated circuit dies 610 and the first redistribution structure 500 can be enhanced.

In an embodiment of the disclosure, a package comprises an interconnect die, an encapsulant, a first redistribution structure, and an integrated circuit die. The interconnect die comprises a semiconductor substrate and an interconnect structure. The interconnect structure is disposed over the semiconductor substrate, and comprising a first test circuit. The encapsulant surrounds the interconnect die. The first redistribution structure is disposed over the interconnect die and the encapsulant. The first redistribution structure comprises a second test circuit, a first test structure, a second test structure, and a plurality of bonding structures. The second test circuit is connected with the first test circuit. The first test structure and the second test structure are connected with the second test circuit. The integrated circuit die is electrically connected to the bonding structures and separated from the first test structure and the second test structure.

In another embodiment of the disclosure, a semiconductor device comprises a plurality of interconnect dies and an encapsulant. Each interconnect die comprises a semiconductor substrate, a through substrate via, and an interconnect structure. The through substrate via is embedded in the semiconductor substrate. The interconnect structure is disposed over the semiconductor substrate and the through substrate via. The interconnect structure comprises a first test circuit. The first test circuit comprises a connection structure, a first conductive via, a second conductive via, a third conductive via, a first contact pad, a second contact pad, and a third contact pad. The first conductive via, the second conductive via and the third conductive via are connected with a top surface of the connection structure. The first contact pad, the second contact pad, and the third contact pad are respectively disposed over and respectively electrically connected with the first conductive via, the second conductive via, and the third conductive via. The encapsulant, surrounds the interconnect die.

A method for manufacturing a package comprises the following steps. A semiconductor structure is provided over a first carrier, wherein the semiconductor structure comprises a semiconductor substrate and an interconnect structure disposed over the semiconductor substrate. The interconnect structure comprises a first test circuit. An encapsulant is applied over the first carrier and surrounding the semiconductor structure. A first redistribution structure is formed over the semiconductor structure and the encapsulant, wherein the first redistribution structure comprises a second test circuit, a first test structure, a second test structure, and bonding structures. The second test circuit is connected with the first test circuit. The first test structure and the second test structure are connected with the second test circuit. The first test structure and the second test structure are probed to conduct an electrical test on the second test circuit and the first test circuit. An integrated circuit die is provided over the bonding structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
an interconnect die, comprising:
a semiconductor substrate; and
an interconnect structure, disposed over the semiconductor substrate, and comprising a first test circuit;
an encapsulant, surrounding the interconnect die;
a first redistribution structure, disposed over the interconnect die and the encapsulant, wherein the first redistribution structure comprises:
a second test circuit, connected with the first test circuit;
a first test structure and a second test structure, connected with the second test circuit; and
a plurality of bonding structures; and
an integrated circuit die, electrically connected to the plurality of bonding structures and separated from the first test structure and the second test structure.

2. The package of claim 1, wherein the first test circuit comprises:
a connection structure;
a first conductive via, a second conductive via, and a third conductive via, electrically connected with the connection structure;
a first contact pad, a second contact pad, and a third contact pad, respectively disposed over and respectively electrically connected with the first conductive via, the second conductive via, and the third conductive via, wherein the second test circuit is disposed over and connected with the first contact pad, the second contact pad, and the third contact pad.

3. The package of claim 2, wherein the second test circuit comprises:
a first contact via, a second contact via, and a third contact via, respectively disposed over and respectively electrically connected with the first contact pad, the second contact pad, and the third contact pad, wherein the first test structure and the second test structure are electrically connected to the first contact via, wherein the first redistribution structure further comprises:
a third test structure, electrically connected to the second contact via;
a fourth test structure, electrically connected to the third contact via, wherein an electrically conductive path between the first test structure and the first contact via, an electrically conductive path between the third test structure and the second contact via and an electrically conductive path between the fourth test structure and the third contact via are separated from each other in the first redistribution structure.

4. The package of claim 2, wherein the first test circuit comprises:
a fourth conductive via, electrically connected with the connection structure;
a fourth contact pad, disposed over and connected with the fourth conductive via, wherein the second test circuit comprises:
a first contact via, a second contact via, a third contact via, and a fourth contact via, respectively disposed over and respectively electrically connected with the first contact pad, the second contact pad, the third contact pad, and the fourth contact pad, wherein the first test structure and the second test structure are electrically connected to the first contact via, wherein the first redistribution structure further comprises:
a third test structure and a fourth test structure, electrically connected to the second contact via;
a fifth test structure and a sixth test structure, electrically connected to the third contact via; and
a seventh test structure and an eighth test structure, electrically connected to the fourth contact via, wherein an electrically conductive path between the first test structure and the first contact via, an electrically conductive path between the third test structure and the second contact via, an electrically conductive path between the fifth test structure and the third contact via, and an electrically conductive path between the seventh test structure and the fourth contact via are separated from each other in the first redistribution structure.

5. The package of claim 1, further comprises:
a plurality of connectors, connecting the integrated circuit die to the plurality of bonding structures; and
an underfill, located between the integrated circuit die and the first redistribution structure, wherein the underfill covers a top surface of the first test structure and a top surface of the second test structure.

6. The package of claim 1, further comprises:
a second redistribution structure, wherein the interconnect die is disposed between the first redistribution structure and the second redistribution structure, wherein the interconnect die comprises a through substrate via disposed within the semiconductor substrate, and the through substrate via is electrically connected the second redistribution structure to the interconnect structure.

7. The package of claim 6, wherein the first test circuit comprises:
a connection structure;
a first conductive via, electrically connected with the connection structure; and
a first contact pad electrically connected with the first conductive via, wherein the interconnect structure comprises a second contact pad electrically connected with the through substrate via, wherein a top surface of the second contact pad is coplanar with a top surface of the first contact pad, and a width of the first contact pad is smaller than a width of the second contact pad.

8. The package of claim 1, wherein the first test structure is located between the integrated circuit die and the semiconductor substrate.

9. A semiconductor device, comprising:
a plurality of interconnect dies, wherein each of the plurality of interconnect dies comprises:
a semiconductor substrate;
a through substrate via, embedded in the semiconductor substrate; and
an interconnect structure, disposed over the semiconductor substrate and the through substrate via, wherein the interconnect structure comprises:
a first test circuit, comprising:
a connection structure;
a first conductive via, a second conductive via, and a third conductive via, connected with a top surface of the connection structure; and
a first contact pad, a second contact pad, and a third contact pad, respectively disposed over and respectively electrically connected with the first conductive via, the second conductive via, and the third conductive via; and
an encapsulant, surrounding the plurality of interconnect die.

10. The semiconductor device of claim 9, wherein the interconnect structure comprises a fourth contact pad electrically connected with the through substrate via, wherein a top surface of the fourth contact pad is coplanar with a top surface of the first contact pad, and a width of the first contact pad is smaller than a width of the fourth contact pad.

11. The semiconductor device of claim 9, further comprises:
a first redistribution structure, disposed over the plurality of interconnect dies and the encapsulant, wherein the first redistribution structure comprises:
a second test circuit, connected with the first test circuit;
a first test structure, a second test structure and a third test structure, connected with the second test circuit; and
a second redistribution structure, wherein the plurality of interconnect dies are disposed between the first redistribution structure and the second redistribution structure.

12. The semiconductor device of claim 11, wherein the first test circuit is electrically isolated from the through substrate via and the second redistribution structure.

13. The semiconductor device of claim 11, further comprises an integrated circuit die disposed over one of the plurality of interconnect dies, wherein a dummy pad of the integrated circuit die is electrically connected with the first test structure.

14. The semiconductor device of claim 9, wherein the connection structure is ring-shaped.

15. A method for manufacturing a package, comprising:
providing a semiconductor structure over a first carrier, wherein the semiconductor structure comprises:
a semiconductor substrate; and
an interconnect structure, disposed over the semiconductor substrate, and comprising a first test circuit;
applying an encapsulant over the first carrier and surrounding the semiconductor structure;
forming a first redistribution structure over the semiconductor structure and the encapsulant, wherein the first redistribution structure comprises:
a second test circuit, connected with the first test circuit;
a first test structure and a second test structure, connected with the second test circuit; and
a plurality of bonding structures;
probing the first test structure and the second test structure to conduct an electrical test on the second test circuit and the first test circuit; and
providing an integrated circuit die over the plurality of bonding structures.

16. The method of claim 15, wherein the first redistribution structure further comprises a third test structure and a fourth test structure, wherein the third test structure and the fourth test structure are electrically connected to the second test circuit, and the electrical test comprises a four point probe resistivity measurement.

17. The method of claim 15, further comprises:
removing the first carrier; and
forming a second redistribution structure over the semiconductor structure and the encapsulant, wherein the semiconductor structure is located between the first redistribution structure and the second redistribution structure.

18. The method of claim 17, further comprises:
forming a plurality of conductive connectors over the second redistribution structure; and
bonding the second redistribution structure to a package substrate by the plurality of conductive connectors.

19. The method of claim 15, further comprises:
forming an underfill between the integrated circuit die and the first redistribution structure, wherein the underfill covers a top surface of the first test structure and a top surface of the second test structure.

20. The method of claim 15, wherein the first test structure, the second test structure and the plurality of bonding structures are simultaneously formed.
